(19) United States
(12) Patent Application Publication
(10) Pub. No.: US 2026/0150598 A1
(43) Pub. Date: May 28, 2026

(54) METHOD FOR PROCESSING A WORKPIECE

(71) Applicant: DISCO CORPORATION, Tokyo (JP)

(72) Inventors: Akira MIZUTANI, Tokyo (JP); Taku IWAMOTO, Tokyo (JP); Hayato IGA, Tokyo (JP); Hayato TANAKA, Tokyo (JP); Kazuya HIRATA, Tokyo (JP)

(21) Appl. No.: 19/385,274

(22) Filed: Nov. 11, 2025

(30) Foreign Application Priority Data
Nov. 28, 2024 (JP) 2024-206909

(51) Int. Cl. H01L 21/268; H01L 21/304

(52) U.S. Cl. CPC H10P 34/42; H10P 52/00

(57) ABSTRACT

A method for processing a workpiece, in which a first workpiece is fixed to a surface of a second workpiece, includes forming a first modified layer along an annular region inside the first workpiece by emitting laser light at a position inward by a predetermined distance from an outer edge of the first workpiece; removing at least a part of an outer peripheral portion of the first workpiece located outward from the first modified layer; thinning the first workpiece to a predetermined thickness; and removing a region of a film formed on the surface of the second workpiece and laminated with the outer peripheral portion of the first workpiece.

### CROSS REFERENCE TO RELATED APPLICATION

This application is based upon and claims the benefit of priority from the prior Japanese Patent Application No. 2024-206909 filed on Nov. 28, 2024; the entire contents of which are incorporated herein by reference.

### FIELD

The present disclosure relates to a method for processing a workpiece.

### BACKGROUND

With recent demands for thinning and higher integration of device chips, three-dimensionally stacked semiconductor wafers (hereinafter referred to as workpieces) have been developed progressively. For example, a TSV (Through-Silicon Via) workpiece enables connection between electrodes of two chips bonded together by means of through electrodes.

Such a workpiece (first workpiece) is bonded to a basal workpiece (second workpiece), and is ground and thinned in the bonded state. Generally, a workpiece is chamfered at an outer edge thereof; therefore, when ground to an extreme thinness, the outer edge of the first workpiece may form a so-called knife edge, which often causes cracks and chipping on the edge during grinding. Such cracks may develop into devices and as a result damage the devices.

As a countermeasure for such a knife edge, a so-called edge trimming technique, in which an outer peripheral portion of the first workpiece is annularly cut, has been developed (see, for example, Japanese Patent Publication No. 4895594). Moreover, a method, in which a modified layer is formed annularly by emitting a laser beam along a boundary of the outer peripheral portion of the first workpiece, and the first workpiece is thereafter thinned by grinding, has been proposed (see, for example, Japanese Patent Application Laid-Open Publication No. 2020-057709).

However, according to the methods disclosed in the above-referenced publications, in a case where the second workpiece has a film formed on an upper surface thereof (a surface to contact the first workpiece), while the first workpiece is being processed by the edge-trimming and thinning, the film may be damaged. Accordingly, if the film peels off in a subsequent process, the damaged film may adhere to and contaminate the workpiece and cause a problem.

### SUMMARY

The present disclosure aims to provide a processing method, by which contamination of a workpiece due to a film peeling off may be suppressed.

According to an aspect of the present disclosure, a method for processing a workpiece, in which a first workpiece is fixed to a surface of a second workpiece, includes forming a first modified layer along an annular region inside the first workpiece by emitting laser light at a position inward by a predetermined distance from an outer edge of the first workpiece; removing at least a part of an outer peripheral portion of the first workpiece located outward from the first modified layer; thinning the first workpiece to a predetermined thickness; and removing a region of a film formed on the surface of the second workpiece and laminated with the outer peripheral portion of the first workpiece.

According to the present disclosure, contamination of a workpiece by a film peeling off may be suppressed.

### BRIEF DESCRIPTION OF THE DRAWINGS

FIG. 1 is a diagram illustrating a workpiece (wafer) according to a first embodiment.

FIG. 2 is a perspective view of a first workpiece according to the first embodiment.

FIG. 3 is a flowchart illustrating steps in a method for processing a workpiece according to the first embodiment.

FIG. 4 is a diagram illustrating a modified layer forming step (forming a modified layer) according to the first embodiment.

FIG. 5 is a partial cross-sectional view illustrating a state in the modified layer forming step (forming a modified layer) according to the first embodiment.

FIG. 6 is a partial cross-sectional view illustrating a state in the modified layer forming step (forming a modified layer) according to the first embodiment.

FIG. 7 is a plan view illustrating positions of modified layers to be formed in the modified layer forming step (forming a modified layer) according to the first embodiment.

FIG. 8 is a diagram illustrating a thinning step (thinning) according to the first embodiment.

FIG. 9 is a partial cross-sectional view illustrating a state in the thinning step (thinning) according to the first embodiment.

FIG. 10 is a diagram illustrating a removal step (removing) according to the first embodiment.

FIG. 11 is a partial cross-sectional view illustrating a state in the thinning step (thinning) according to the first embodiment.

FIG. 12 is a diagram illustrating a film removal step (removing a film) according to the first embodiment.

FIG. 13 is a partial cross-sectional view illustrating a state in the film removal step (removing a film) according to the first embodiment.

FIG. 14 is a flowchart illustrating steps in a modified example of the method for processing a workpiece according to the first embodiment.

FIG. 15 is a flowchart illustrating steps in the method for processing a workpiece according to the second embodiment.

FIG. 16 is a partial cross-sectional view illustrating a state in the modified layer forming step (forming a modified layer) according to the second embodiment.

FIG. 17 is a partial cross-sectional view illustrating a state in the modified layer forming step (forming a modified layer) according to the second embodiment.

FIG. 18 is a partial cross-sectional view illustrating a state in the thinning step (thinning) according to the second embodiment.

FIG. 19 is a flowchart illustrating steps in a modified example of the method for processing a workpiece according to the second embodiment.

FIG. 20 is a flowchart illustrating steps in a method for processing a workpiece according to a third embodiment.

FIG. 21 is a partial cross-sectional view illustrating a state in the thinning step (thinning) according to the third embodiment.

FIG. 22 is a partial cross-sectional view illustrating a state in the thinning step (thinning) according to the first embodiment.

### DESCRIPTION OF EMBODIMENTS

Hereinafter, embodiments of the present disclosure will be described with reference to the drawings.

### First Embodiment

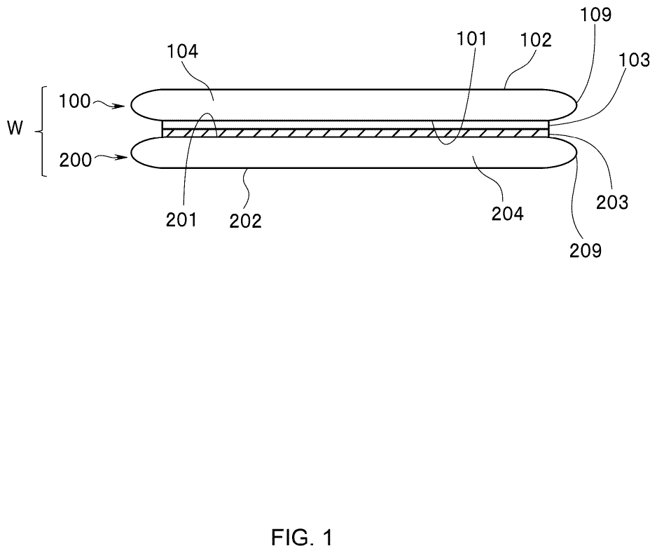

In the present disclosure, a term such as “xx step” may be interpreted (equated) as “xx-ing.” For example, terms “modified layer forming step” and “modified layer forming process” may be read as “forming a modified layer,” terms “thinning step” and “thinning process” may be read as “thinning,” terms “removal step” and “removal process” may be read as “removing,” terms “film removal step” and “film removal process” may be read as “removing a film,” and terms “surface treatment step” and “surface treatment process” may be read as “treating a surface.” First, a configuration of a workpiece W as an object to be processed will be described. FIG. 1 is a diagram illustrating a workpiece (wafer) according to a first embodiment. The workpiece W is a so-called bonded workpiece formed by bonding one surface 101 of a first workpiece 100 and one surface 201 of a second workpiece 200 to each other. In the following description, in each of the first workpiece 100 and the second workpiece 200, the bonded surface is referred to as a front surface, and a surface opposite to the bonded surface is referred to as a back surface. In other words, a surface 101 of the first workpiece 100 is referred to as a front surface 101, and the other surface 102 is referred to as a back surface 102. Further, a surface of the second workpiece 200 is referred to as a front surface 201, and the other surface 202 is referred to as a back surface 202.

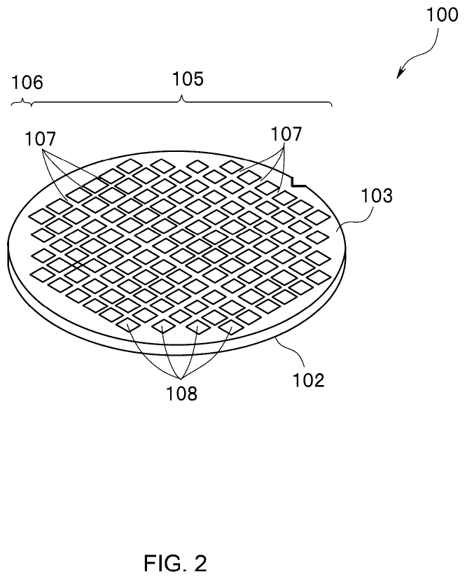

The first workpiece 100 may be, for example, a disk-shaped semiconductor workpiece or optical device workpiece in which a substrate 104 is made of silicon (Si), sapphire (Al2O3), gallium arsenide (GaAs), silicon carbide (SiC), or the like. The first workpiece 100 has an outer edge 109, which is chamfered such that a central portion in a thickness direction projects most outwardly, forming an arc-curved cross-section from the front surface 101 to the back surface 102 of the substrate 104. The first workpiece 100 includes a device layer 103 on the front surface 101 side of the substrate 104. FIG. 2 is a perspective view of the first workpiece according to the first embodiment. As shown in FIG. 2, the device layer 103 includes a central region 105 and an outer peripheral excess region 106 that surrounds the central region 105. In the central region 105, devices 108 are formed in respective regions that are partitioned by a plurality of predetermined dividing lines 107 that intersect with each other. The device 108 is an integrated circuit such as an IC (Integrated Circuit) or LSI (Large Scale Integration). The outer peripheral excess region 106 is a region surrounding the central region 105 of the device layer 103 and is a region in which no device 108 is formed.

The second workpiece 200 may be, for example, a disk-shaped semiconductor workpiece or optical device workpiece in which a substrate 204 is made of silicon (Si), sapphire (Al2O3), gallium arsenide (GaAs), silicon carbide (SiC), or the like. The second workpiece 200 has an outer edge 209, which is chamfered such that a central portion in a thickness direction projects most outwardly, forming an arc-curved cross-section from the front surface 201 to the back surface 202 of the substrate 204. The second workpiece 200 includes a film 203 formed on the front surface 201 side of the substrate 204. The film 203 may be, for example, an oxide film (SiO2), a nitride film (SiN), an oxynitride film (SiON), or a metal film (for example, Cu). Optionally, the second workpiece 200 may include a device layer between the substrate 204 and the film 203.

The first workpiece 100 and the second workpiece 200 are bonded, for example, by joining the front surface 101 of the first workpiece 100 and the front surface 201 of the second workpiece 200 together and integrally bonding them by a siloxane bond to form the workpiece W.

The first workpiece 100 and the second workpiece 200 may be bonded, for example, in a way as follows. First, plasma treatment is applied on at least one of the surfaces (front surfaces 101, 201) of the first workpiece 100 and the second workpiece 200 that form the bonded surface. By applying the plasma treatment, surface impurities such as organic substances adhered to the front surfaces 101, 201 are removed, and clean surfaces are exposed. Further, to the dangling Si species on the exposed clean front surfaces 101, 201, hydroxyl groups (OH groups) bond. In other words, hydroxyl groups are formed on the front surfaces 101, 201 activated by the plasma treatment.

Next, the front surface 101 of the first workpiece 100 and the front surface 201 of the second workpiece 200 are attached together. In this instance, a hydrogen atom (H) of the hydroxyl groups formed on the front surface 101 side of the first workpiece 100 forms a hydrogen bond with an oxygen atom (O) of the hydroxyl groups formed on the front surface 201 side of the second workpiece 200. Moreover, a hydrogen atom (H) of the hydroxyl groups formed on the front surface 201 side of the second workpiece 200 forms a hydrogen bond with an oxygen atom (O) of the hydroxyl groups formed on the front surface 101 side of the first workpiece 100. Accordingly, the first workpiece 100 and the second workpiece 200 attract each other by hydrogen bonding and are bonded temporarily. A bonding strength at the time of the temporary bonding by the hydrogen bonding may be, for example, approximately 10 to 200 J/m\hat{ }2.

Finally, the temporarily bonded workpiece W is processed through an annealing treatment by using a method such as RTA (Rapid Thermal Anneal). In the heated workpiece W, a dehydration-condensation reaction occurs at a bonding interface between the first workpiece 100 and the second workpiece 200. In other words, loss of water (H2O) from the hydroxyl groups formed on the front surfaces 101, 201 results in a covalent bond via an oxygen atom (O), thereby increasing the bonding strength between the front surface 101 of the first workpiece 100 and the front surface 201 of the second workpiece 200. The bonding strength due to a siloxane bond may be, for example, approximately 1000 to 20000 J/m\hat{ }2.

As such, the siloxane bond is an Si—O—Si bond in which silicon (Si) and oxygen (O) are alternately bonded, and since the first workpiece 100 and the second workpiece 200 are joined by heating, the bonded state is securely maintained even in a high temperature environment.

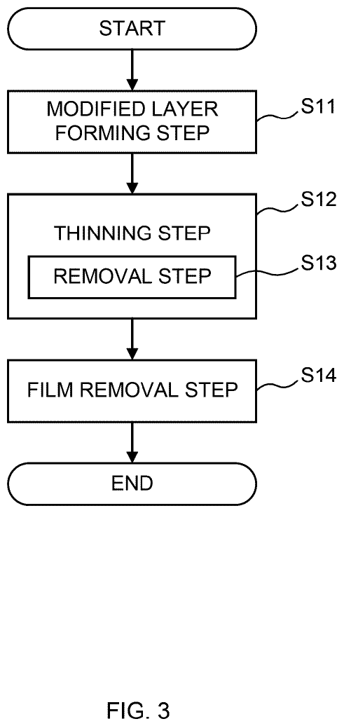

Next, a method for processing the workpiece W according to the present embodiment will be described. FIG. 3 is a flowchart illustrating steps in the method for processing a workpiece according to the first embodiment. As shown in FIG. 3, the method for processing a workpiece according to the first embodiment includes four steps: a modified layer forming step (S11), a thinning step (S12), a removal step (S13), and a film removal step (S14). Hereinafter, the steps will be described in detail.

First, in the modified layer forming step, a modified layer is formed in the substrate 104 of the first workpiece 100 (S11). The modified layer means a region in which density, refractive index, mechanical strength, or other physical properties are changed to a different state from those of a surrounding region by irradiation with laser light LB. The modified layer is, for example, a melt-treated region, a cracked region, a dielectric breakdown region, a refractive-index changed region, or a region in which these regions are mixed. The modified layer has lower mechanical strength and the like than other portions of the first workpiece 100. In the modified layer forming step (S11) in the first embodiment, two modified layers (first modified layer 11, second modified layer 21) are formed inside the first workpiece 100.

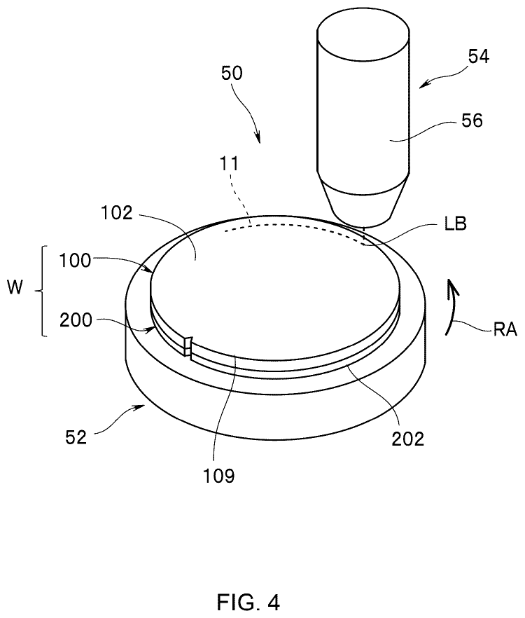

FIG. 4 is a diagram illustrating the modified layer forming step according to the first embodiment. The first modified layer 11 and the second modified layer 21 are formed using a laser processing apparatus 50 (partly shown) in FIG. 4. The laser processing apparatus 50 includes a holder table 52 and a laser beam emitting unit 54. The holder table 52 is capable of holding the workpiece W on a holder surface and is rotatable about a vertical axis. The laser beam emitting unit 54 emits laser light LB at the workpiece W held on the holder table 52. The laser light LB is a laser beam having a wavelength transmissive through the first workpiece 100 and may be, for example, infrared rays (IR). The laser beam emitting unit 54 includes a focusing device 56 that locates a focal point of the laser light LB at a desired position. The laser processing apparatus 50 further includes an unillustrated moving unit for moving the holder table 52 and the laser beam emitting unit 54 relatively, and an unillustrated image-capturing unit for capturing an image of the workpiece W held on the holder table 52.

Using the laser processing apparatus 50 described above, the first modified layer 11 is formed. First, the back surface 202 side of the second workpiece 200 is held by suction on the holder surface (upper surface) of the holder table 52. Next, the first workpiece 100 and the focusing device 56 of the laser beam emitting unit 54 are aligned with each other. Specifically, by the unillustrated moving unit, the holder table 52 is moved to an irradiative region below the laser beam emitting unit 54. Next, by capturing an image of the first workpiece 100 with the unillustrated image-capturing unit and aligning the first workpiece 100, an emitter of the laser beam emitting unit 54 is located to vertically face toward a position, which is at a predetermined distance inward from an outer edge 109 of the first workpiece 100, and thereafter a focal point of the laser light LB is set to a position inside the first workpiece 100.

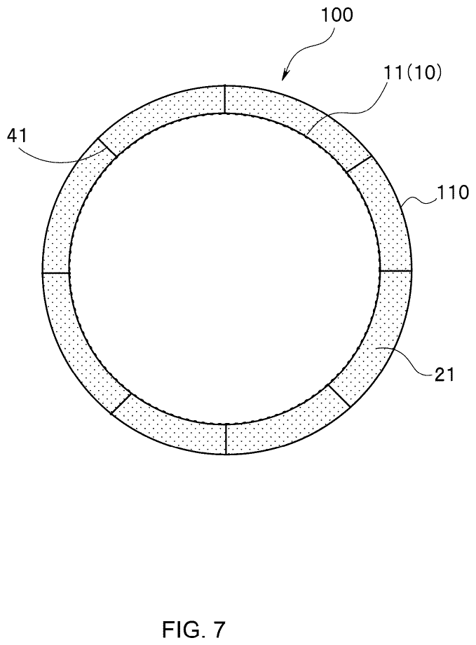

Next, while rotating the holder table 52 about the vertical axis, the laser beam emitting unit 54 emits the laser light LB in pulses onto the back surface 102 side of the first workpiece 100. In other words, the laser light LB is emitted annularly along the position located inward by the predetermined distance from the outer edge 109 of the first workpiece 100. Accordingly, the first modified layer 11 is formed in an annular region 10 (see FIG. 7) set at the position located inward by the predetermined distance from the outer edge 109 of the first workpiece 100. From the first modified layer 11, a crack 12 develops, and the first modified layer 11 and the crack 12 joining together form a separation starting point at the position located inward by the predetermined distance from the outer edge 109 of the first workpiece 100. The annular region 10 at the position inward by the predetermined distance from the outer edge 109 is, for example, located at a boundary between the central region 105 and the peripheral excess region 106.

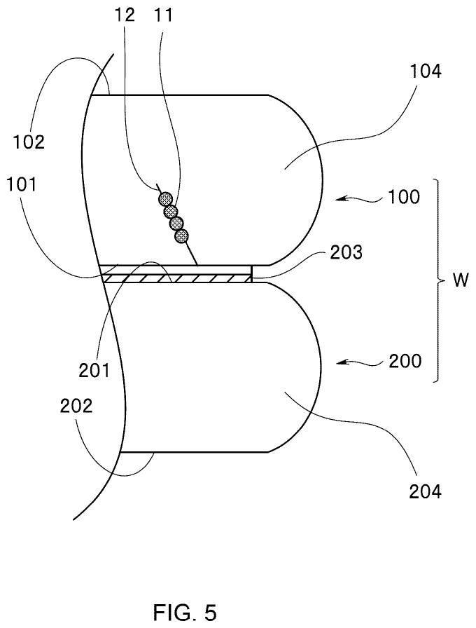

FIG. 5 is a partial cross-sectional view illustrating a state in the modified layer forming step according to the first embodiment. FIG. 5 is a partial cross-sectional view of the workpiece W when the first modified layer 11 is being formed. As shown in FIG. 5, in the modified layer forming step, preferably, the first modified layer 11 is formed such that the crack 12 developed from the first modified layer 11 reaches the front surface 101 side of the first workpiece 100.

In forming the first modified layer 11, preferably, the focal point of the laser light LB may be changed, and the laser light LB may be emitted multiple times to form a plurality of annular first modified layers 11 in the thickness direction of the first workpiece 100. In this case, the annular first modified layers 11 are sequentially formed from the front surface 101 side toward the back surface 102 side. For example, for forming four annular first modified layers 11, first, a first one of the annular first modified layers 11 is formed, with a focal point of the laser light LB located at a position close to the front surface 101 (for example, at a depth of 700 μm from the back surface 102), by emitting the laser light LB and rotating the holder table 52. Thereafter, while the holder table 52 is rotated, the focal point is shifted stepwise three times toward the back surface 102 side (upward), for example, to depths of 500 μm, 300 μm, and 150 μm from the back surface 102, thereby forming a total of four annular first modified layers 11. For forming the first modified layers 11 to be connected by cracks that are developed from these modified layers, the adjacent modified layers may be formed to be spaced apart from each other in at least one of the depth direction or a planar direction. If connecting the adjacent first modified layers 11 by a crack is difficult, the modified layers may be formed to overlap in at least one of the depth direction or the planar direction.

Note that the annular first modified layer 11 is not limited to four layers but may be five or more layers or three or fewer layers. The positions (depths) for forming the layers in the thickness direction are not limited to the above-mentioned depths but may be set to any preferable depths according to, for example, the thickness of the first workpiece 100.

Preferably, the first modified layers 11 may be formed such that the closer the first modified layer 11 is to the back surface 102, which is the laser incident surface opposite to the bonding interface, by the farther distance the first modified layer 11 and the outer edge 109 are apart. In other words, preferably, the crack 12 connecting the first modified layers 11 laminated in the thickness direction is formed to incline outwardly, in a cross-sectional view with the laser incident surface located on the upper side, from the center of the first workpiece 100, as shown in FIG. 5. However, as long as the crack 12 intersects the front surface 101, which is the surface opposite to the laser incident surface, the crack 12 may be perpendicular to the front surface 101 or may incline in the opposite direction to that shown in FIG. 5 (from the outside toward the center of the first workpiece 100).

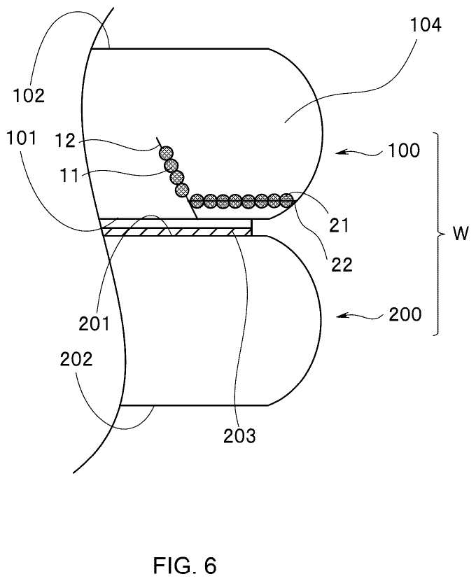

Next, second modified layer 21 is formed. FIG. 6 is a partial cross-sectional view illustrating a state in the modified layer forming step according to the first embodiment. FIG. 6 is a partial cross-sectional view of the workpiece W when the second modified layer 21 is being formed. While maintaining the focal point of the laser light LB at a substantially constant height, the laser light LB is emitted at predetermined intervals into a region outside the annular region 10 of the first workpiece 100 by moving the emitter of the laser beam emitting unit 54 or a position of the holder table 52 in the horizontal direction. In other words, the second modified layers 21 are formed along the planar direction of the workpiece W over the entire region outside the annular region 10 where the first modified layers 11 are formed. For forming adjacent second modified layers 21 to be connected by a crack developed from these modified layers, the adjacent modified layers may be formed to be spaced apart from one another in the planar direction of the workpiece W. If connecting the adjacent second modified layers 21 by a crack is difficult, the modified layers may be formed to overlap in the planar direction.

Note that the second modified layers 21 may be formed in a direction shifted to some extent from the planar direction of the first workpiece 100 (or the second workpiece 200) rather than completely parallel to the planar direction as long as the second modified layers 21 are formed on a plane along a direction substantially the same as the planar direction of the first workpiece 100 (or the second workpiece 200). Preferably, the second modified layer 21 may be formed in proximity to the front surface 101. From the second modified layers, a crack 22 develops, and the second modified layers 21 and the crack 22 joining together form a separation starting point in the thickness direction in the outer peripheral excess region 106 of the first workpiece 100.

Note that, when the laser light is emitted from the front surface 101 side, in a region below the first modified layer 11, the laser light is dispersed by the first modified layer 11; therefore, the laser light LB may not irradiate the region accurately.

Accordingly, if the first modified layers 11 are formed such that the crack 12 connecting the first modified layers 11 laminated in the thickness direction inclines in the direction opposite to that shown in FIG. 5 (i.e., toward the center of the first workpiece 100 from the outside in the cross-sectional view with the laser incident surface located on the upper side), emission from the front surface 101 side is hindered by the first modified layers 11, and an edge of the first modified layer 11 (and the crack 12) on the inner side and an edge of the second modified layer 21 (and the crack 22) toward the center may not be formed close to each other.

In contrast, when the crack 12 connecting the first modified layers 11 laminated in the thickness direction is formed to incline outward from the center of the first workpiece 100, the laser light incident even from the front surface 101 is less likely to be dispersed by the first modified layers 11. Therefore, as shown in FIG. 6, the second modified layers 21 may be formed close to the first modified layer 11 and the crack 12. As such, the separation starting point in the planar direction, which is formed of the first modified layers 11 and the crack 12 joining together, and the separation starting point in the thickness direction, which is formed of the second modified layers 21 and the crack 22 joining together, are formed in proximity to each other, thereby enabling removal of an outer peripheral portion of the first workpiece 100 easily in a subsequent removal step. Therefore, when the annular first modified layers 11 are formed in the layered manner, the layers may preferably be formed such that, the closer the layer is to the back surface 102, by the farther distance the first modified layer 11 and the outer edge 109 are apart.

In the modified layer forming step described above, for example, as shown in FIG. 7, a radial fourth modified layer 41 extending from the annular region 10 where the annular first modified layers 11 are formed toward the outer edge 109 may be formed. FIG. 7 is a plan view illustrating positions of the modified layers to be formed in the modified layer forming step according to the first embodiment. The fourth modified layer 41 is a modified layer that functions to subdivide more finely a chamfered annular region (hereinafter referred to as a chamfered portion) 110, which is a part of the outer peripheral portion of the first workpiece 100, when the chamfered portion 110 is removed in a subsequent removal step. For example, the fourth modified layer 41 may be formed by emitting the laser light LB from the back surface 102 side of the first workpiece 100 under laser processing conditions similar to those for forming the first modified layer 11. The fourth modified layer 41 is formed at a plurality of positions (eight positions in FIG. 7) at equal intervals along the outer periphery of the first workpiece 100. By forming the fourth modified layers 41, the chamfered portion 110 may be finely divided in the removal step described later, thereby enabling easy removal of the chamfered portion 110 from the first workpiece 100. Note that the fourth modified layers 41 are not necessarily formed radially but may be formed in a grid pattern or an annular pattern continuously or discontinuously.

By the modified layer forming step described above, as shown in FIG. 7, the first modified layers 11 are formed annularly in the first workpiece 100. Moreover, the second modified layers 21 are formed along the planar direction of the workpiece W over the entire region located outside the first modified layer 11. Furthermore, the fourth modified layers 41 radially extending from the first modified layer 11 toward the outer edge 109 are formed.

Next, in the thinning step, an exposed surface (back surface 102) side of the first workpiece 100 forming the workpiece W is ground to be thinned to a finished thickness (S12). In the present embodiment, while the thinning step (S12) is being performed, the removal step (S13) is performed simultaneously. The removal step is a process in which the chamfered portion 110 partitioned by the first modified layer 11 and the second modified layer 21 is separated and removed from the workpiece W.

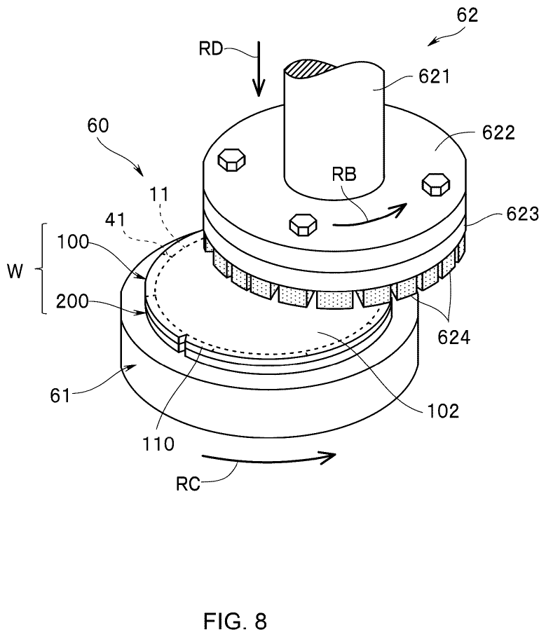

Thinning of the first workpiece 100 is performed using a grinding apparatus 60 (partially shown) illustrated in FIG. 8. FIG. 8 is a diagram illustrating the thinning step according to the first embodiment. The grinding apparatus 60 includes a grinder 62 for grinding and thinning the workpiece W, which is held by suction on a holder table 61. The grinder 62 includes a rotary spindle 621 rotated by a rotary drive mechanism (not shown), a wheel mount 622 attached to a lower end of the rotary spindle 621, and a grinding wheel 623 attached to a lower surface of the wheel mount 622. On a lower surface of the grinding wheel 623, a plurality of grindstones 624 are arranged annularly.

As shown in FIG. 8, the workpiece W is placed on the holder table 61 with the back surface 202 side of the second workpiece 200 facing downward, and is held by suction by operating a suctioning device (not shown). Next, the rotary spindle 621 of the grinder 62 is rotated, for example, at 6000 rpm in a direction indicated by arrow RB in FIG. 8, while the holder table 61 is rotated, for example, at 300 rpm in a direction indicated by arrow RC. Further, while grinding water is supplied onto the back surface 102 of the first workpiece 100 by a grinding water supplying device (not shown), a grind-feeding device (not shown) is activated to move the grindstones 624 to contact the back surface 102 of the first workpiece 100. Furthermore, by moving the grinding wheel 623 downward in a direction indicated by arrow RD at a grinding feed rate of, for example, 0.1 μm/sec, the back surface 102 of the first workpiece 100 is ground with the grindstones 624 and thinned to a predetermined finished thickness.

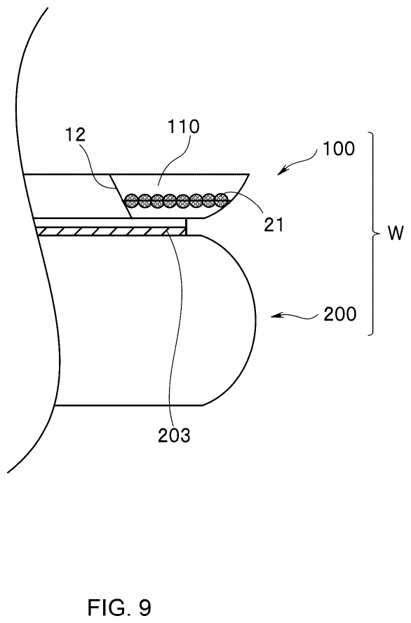

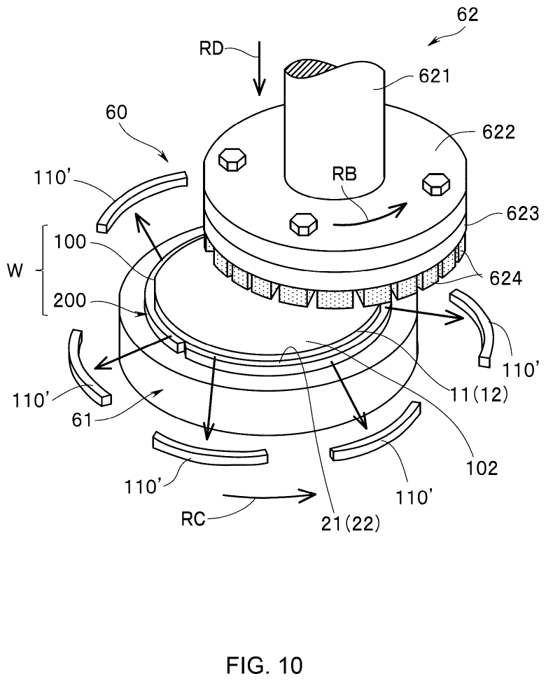

FIG. 9 is a partial cross-sectional view illustrating a state in the thinning step according to the first embodiment. As the first workpiece 100 is thinned further by grinding, the crack 12 appears exposed from the upper surface, as shown in FIG. 9. In this state, when grinding with the grindstones 624 progresses further, as shown in FIG. 10, the grinding force acts from the back surface 102 side of the first workpiece 100 as an external force, and the chamfered portion 110 is removed from the workpiece W where the first modified layer 11 and the second modified layer 21 act as the separation starting points. FIG. 10 is a diagram illustrating the removal step according to the first embodiment. In this instance, with the fourth modified layers 41 having been formed, the annular chamfered portion 110 is divided at the fourth modified layers 41 acting as starting points, and may be removed easily as scraps 110′.

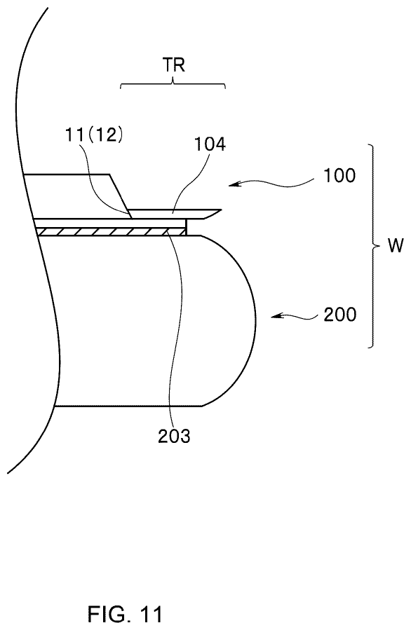

FIG. 11 is a partial cross-sectional view illustrating a state in the thinning step according to the first embodiment. FIG. 11 is a partial cross-sectional view of the workpiece W at the end of the thinning step. When the thinning step (also performed as the removal step) is completed, the thickness of the first workpiece 100 at a region on the central side with respect to the first modified layer 11 (crack 12) is reduced to a predetermined thickness. Further, in a region located outward from the first modified layer 11 (crack 12), which will be hereinafter referred to as a trimming region TR, the chamfered portion 110 is removed and the substrate 104 of the first workpiece 100 is exposed. In other words, at the time when the thinning step (doubling as the removal step) is completed, a part of the outer peripheral portion of the first workpiece 100 remains in the trimming region TR on the bonding surface between the first workpiece 100 and the second workpiece 200.

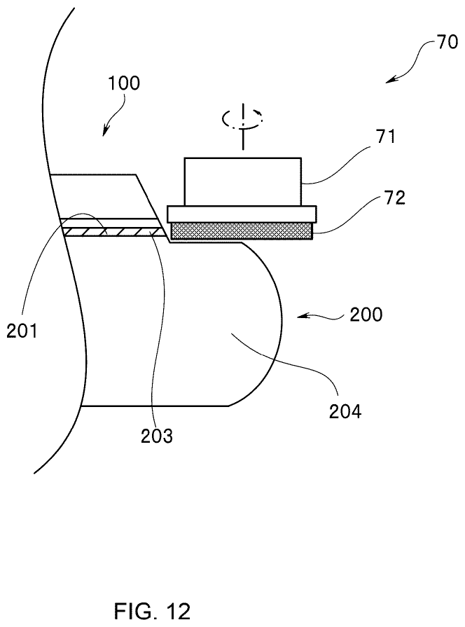

Therefore, the film removal step is performed lastly to remove the remainder of the outer peripheral portion of the first workpiece 100 and the film 203 in the trimming region TR (S14). FIG. 12 is a diagram illustrating the film removal step according to the first embodiment. The film 203 and the like is removed using a polishing apparatus 70 (partially shown) illustrated in FIG. 12.

The polishing apparatus 70 includes a base 71 that is rotatable about a vertical axis by a rotary drive means (not shown), and a polishing pad 72 attached to a lower surface of the base 71. The workpiece W is held by suction on a holder table (not shown). While supplying slurry (not shown), the polishing pad 72 is moved to contact the exposed surface (upper surface) of the trimming region TR. Further, while rotating around the axis, the polishing pad 72 is pressed downward to polish the exposed surface (upper surface) of the trimming region TR. By polishing, the layers laminated in the trimming region TR (remainder of the outer peripheral portion of the first workpiece 100 and the film 203) are removed. In order to prevent incomplete removal of the film 203, preferably, polishing is continued after removal of the film 203 so that a region of the substrate 204 of the second workpiece 200 laminated with the film 203 is also partially removed.

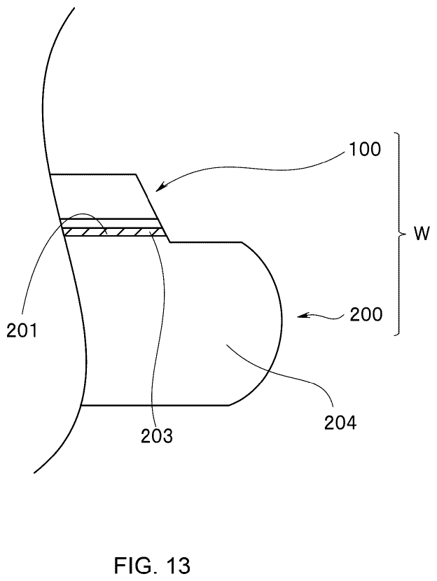

FIG. 13 is a partial cross-sectional view illustrating a state in the film removal step according to the first embodiment. FIG. 13 is a partial cross-sectional view of the workpiece W at the end of the film removal step. As shown in FIG. 13, when the film removal step is completed, a region of the film 203 formed on the front surface 201 of the second workpiece 200, which was laminated with the outer peripheral portion of the first workpiece, is removed. In other words, a region of the film 203 formed on the front surface 201 of the second workpiece 200, which was exposed after removal of the remainder of the outer peripheral portion of the first workpiece 100, is removed. Further, a region of the second workpiece 200 laminated with the removed film 203 is also removed by a predetermined thickness.

As described above, according to the present embodiment, when thinning the workpiece W in which the first workpiece 100 and the second workpiece 200 are bonded and the film 203 is formed on the bonding surface between the first workpiece 100 and the second workpiece 200, the film removal step is performed after removing the chamfered portion 110, which is partitioned by the first modified layer 11 and the second modified layer 21, in the removal step. In the film removal step, the remaining outer peripheral portion of the first workpiece 100 and the region of the film 203 laminated with the outer peripheral portion are removed. In other words, according to the present embodiment, when thinning the workpiece W, a region of the film 203 exposed on the workpiece W is removed, thereby suppressing contamination of the workpiece W by the film 203 that may otherwise peel off in a subsequent process.

In the above description, in the thinning step, the first workpiece 100 is thinned by grinding using the grinding apparatus 60. However, the method for thinning is not limited thereto. For example, other methods such as polishing using a polishing pad or cutting using a bite cutting apparatus may be employed. Further, the above described that, in the film removal step, the film 203 is removed by polishing using the polishing apparatus 70. However, the method for removing is not limited thereto. For example, other methods such as peeling using a cutting blade, grinding using a grinding wheel, dry etching by plasma etching, wet etching using chemicals, or laser removal by irradiation with laser light may be employed.

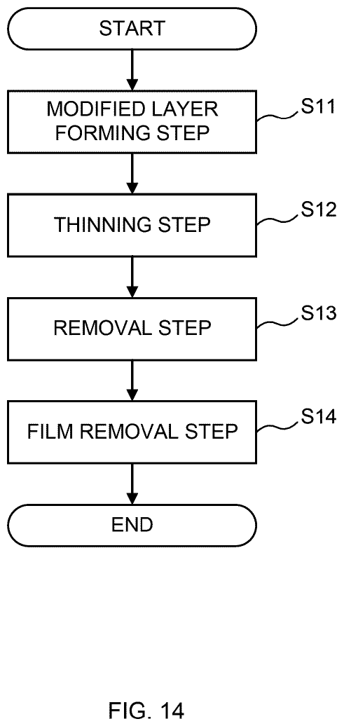

Further, in the above description, the thinning step and the removal step are performed simultaneously by the grinding apparatus 60 described above; however, optionally, these steps may be performed at different timings. FIG. 14 is a flowchart illustrating steps in a modified example of the method for processing a workpiece according to the first embodiment. As shown in FIG. 14, after the first workpiece 100 is thinned to the predetermined thickness in the thinning step (S12), the removal step (S13) may be performed using the same grinding apparatus 60 as that in the thinning step. Or, the removal step (S13) may be performed after the modified layer forming step (S11), and the thinning step (S12) may be performed with the chamfered portion 110 having been removed from the first workpiece 100. In other words, the thinning step (S12) and the removal step (S13) may be performed in either order or may be performed simultaneously.

Furthermore, as in the modified example shown in FIG. 14, when the removal step is performed independently, removal of the chamfered portion 110 in the removal step is not limited to the method using the external force applied by the grinding apparatus 60 described above, but other external forces generated in other methods may be used. For example, a bite cutting apparatus may be used to apply stress load generated by a cutting blade as the external force, or a separating member such as a wedge or fluid may be inserted into the interface of the second modified layer to separate the chamfered portion 110.

### Second Embodiment

The method for processing a workpiece according to a second embodiment differs from the first embodiment in that the position of the modified layer formed in the modified layer forming step is different. Further, the second embodiment also differs in that the film removal step is performed simultaneously with the removal step, and in that a surface treatment step is performed after the film removal step. Hereinbelow, the differences from the first embodiment will be described.

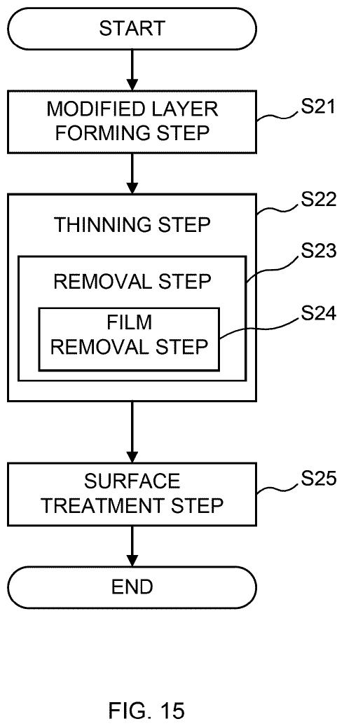

FIG. 15 is a flowchart illustrating steps in the method for processing a workpiece according to the second embodiment. As shown in FIG. 15, the method processing a workpiece according to the second embodiment includes five steps: a modified layer forming step (S21), a thinning step (S22), a removal step (S23), a film removal step (S24), and a surface treatment step (S25).

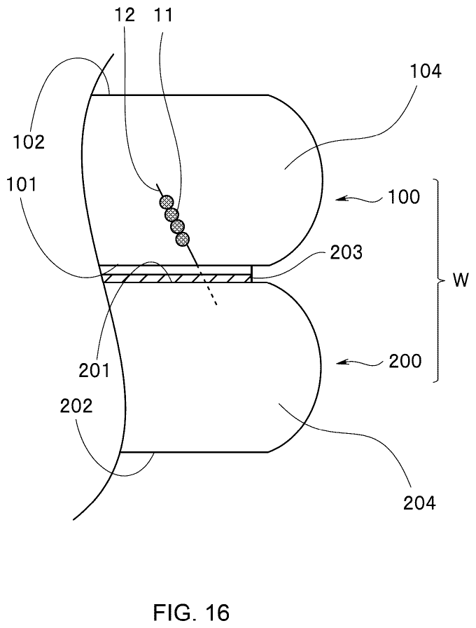

In the modified layer forming step (S21), two modified layers (first modified layer 11, third modified layer 31) are formed. The first modified layer 11 is formed inside the first workpiece 100 in the same manner as that in the first embodiment. FIG. 16 is a partial cross-sectional view illustrating a state in the modified layer forming step according to the second embodiment. FIG. 16 is a partial cross-sectional view of the workpiece W when the first modified layer 11 is being formed. The method for forming the first modified layer 11 in the present embodiment is performed using the laser processing apparatus 50 in the same manner as that in the first embodiment. The position to form the first modified layer 11 in the first workpiece 100 is also the same as that in the first embodiment. Meanwhile, as shown in FIG. 16, in the present embodiment, the crack 12 developed from the first modified layers 11 preferably protrudes through the interface between the first workpiece 100 and the second workpiece 200 and extends into the second workpiece 200. However, the crack 12 may merely reach to appear on the front surface 101 of the first workpiece 100, similarly to that in the first embodiment.

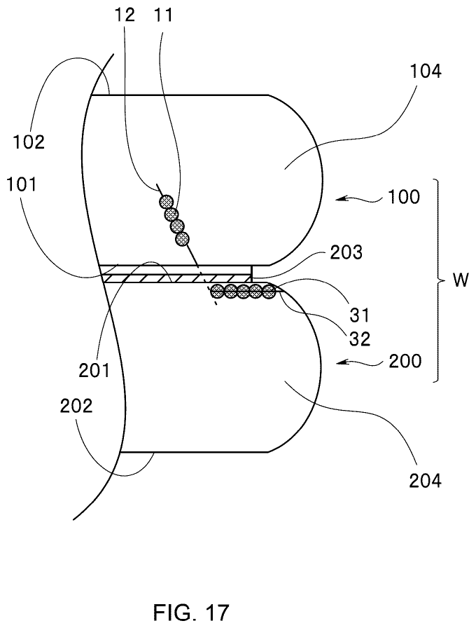

FIG. 17 is a partial cross-sectional view illustrating a state in the modified layer forming step according to the second embodiment. FIG. 17 is a partial cross-sectional view of the workpiece W when the third modified layer 31 is being formed. The third modified layer 31 is formed, similarly to the second modified layer 21, inside the second workpiece 200 over the entire region outward from the annular region 10 where the first modified layer 11 is formed, along the planar direction of the workpiece W. The method for forming the third modified layer 31 in the present embodiment is the same as the method for forming the second modified layer 21 in the first embodiment, except for the height of the focal point of the laser light LB. The third modified layer 31 may be formed on a plane substantially parallel to the planar direction of the second workpiece 200 (or the first workpiece 100), and need not be exactly parallel but may be formed in a direction slightly deviated from the planar direction. The third modified layer 31 is preferably formed in proximity to the front surface 201, which is close to the bonding interface between the two workpieces, on the side opposite to the laser incident surface. Optionally, in the modified layer forming step, fourth modified layers 41 may also be formed in the same manner as those in the first embodiment.

The subsequent thinning step is performed in the same manner as that in the first embodiment, for example, by grinding the exposed surface (back surface 102) of the first workpiece 100 using the grinding apparatus 60 to a finished thickness (S22). While the thinning step (S22) is being performed, the removal step (S23) is performed simultaneously. The removal step is a process in which the chamfered portion 110 partitioned by the first modified layer 11 and the third modified layer 31 is separated and removed from the workpiece W. In the present embodiment, the removal step (S23) is also performed as the film removal step (S24). This is because the region of the film 203 to be removed in the film removal step (S24) corresponds to the region of the film 203 formed on the front surface 201 of the second workpiece 200 that is included in the chamfered portion 110 (i.e., the region laminated with the peripheral portion of the first workpiece). Therefore, once the chamfered portion 110 is removed in the removal step, the film removal step is also performed simultaneously.

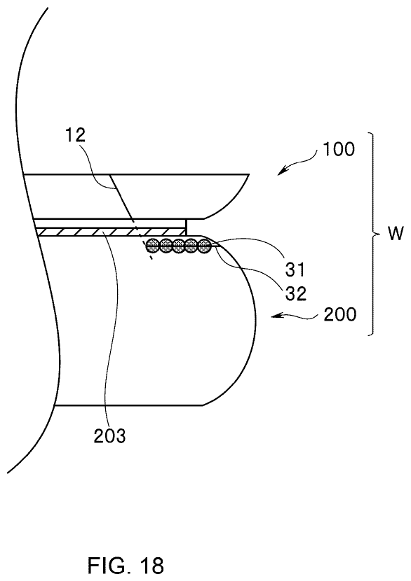

FIG. 18 is a partial cross-sectional view illustrating a state in the thinning step according to the second embodiment. As the first workpiece 100 is thinned further by grinding, the crack 12 appears exposed from the upper surface, as shown in FIG. 18. In this state, when grinding with the grindstones 624 progresses further, the grinding force acts from the back surface 102 side of the first workpiece 100 as an external force, and the chamfered portion 110 is removed from the workpiece W where the first modified layer 11 and the third modified layer 31 act as the separation starting points. After the chamfered portion 110 has been removed, grinding is further continued to thin the first workpiece 100 to the predetermined finished thickness, as shown in FIG. 13, whereby the workpiece W is processed into the same shape as that of the workpiece W in the first embodiment when the film removal step is completed.

In the present embodiment, if roughness of the surface of the substrate 204 of the second workpiece 200 exposed after removal of the chamfered portion 110 is large, fragments may fall off, and particles that may contaminate the workpiece W may be generated. Therefore, in the present embodiment, preferably, the surface treatment step is performed after completion of the thinning step.

The surface treatment step includes, for example, polishing the region of the substrate 204 of the second workpiece 200 exposed on the upper surface of the workpiece W with a polishing pad, thereby reducing the roughness of the surface (S25). The method to be used in the surface treatment step is not limited to the above polishing, but other methods may be employed, such as grinding with a grinding wheel having a smaller abrasive grain size than that used in the removal step, cutting with a cutting blade, chemical etching with a liquid, plasma etching, or a method of irradiating with a laser light LB to melt and planarize the surface.

As described above, in the present embodiment, by forming the third modified layer 31 along the planar direction of the workpiece W in the region inside the second workpiece 200 in proximity to the front surface 201, the region of the film 203 to be removed may be included in the chamfered portion 110. Thus, by executing the thinning step, the film removal step in addition to the removal step is performed. Accordingly, the region of the film 203 that is exposed on the workpiece W may be removed more easily than in the first embodiment. Therefore, similarly to the first embodiment, contamination of the workpiece the film 203 that may otherwise peel off in a subsequent process may be suppressed.

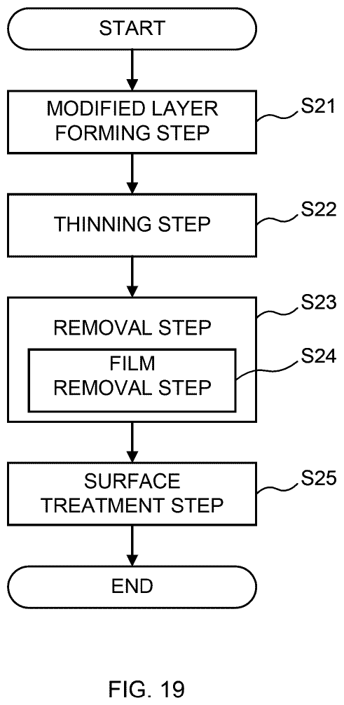

In the foregoing description, the thinning step and the removal step (also performed as the film removal step) are performed simultaneously using the grinding apparatus 60 described above; however, these steps may be performed at different timings. FIG. 19 is a flowchart illustrating steps in a modified example of the method for processing a workpiece according to the second embodiment. As shown in FIG. 19, after the first workpiece 100 is thinned to the predetermined thickness in the thinning step (S22), the removal step (S23), which is also performed as the film removal step (S24), may be performed using the same grinding apparatus 60 as that in the thinning step. Or, the removal step (S23) may be performed after the modified layer forming step (S21), and the thinning step (S22) may be performed with the chamfered portion 110 having been removed from the workpiece W. In other words, the thinning step (S22) and the removal step (S23), which is also performed as the film removal step (S24), may be performed in either order or may be performed simultaneously.

Furthermore, as in the modified example shown in FIG. 19, when the removal step is performed independently, removal of the chamfered portion 110 in the removal step is not limited to the method using the external force applied by the grinding apparatus 60 described above, but other external forces generated in other methods may be used. For example, a bite cutting apparatus may be used to apply stress load generated by a cutting blade as the external force, or a separating member such as a wedge or fluid may be inserted into the interface of the third modified layer 13 to separate the chamfered portion 110.

### Third Embodiment

The method for processing a workpiece according to a third embodiment differs from the first embodiment in that solely the first modified layer 11 is formed in the modified layer forming step. Hereinbelow, the differences from the first embodiment will be described.

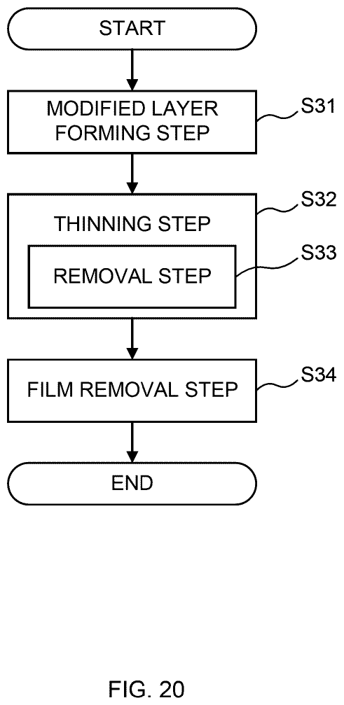

FIG. 20 is a flowchart illustrating steps in the method for processing a workpiece according to the third embodiment. As shown in FIG. 20, the method for processing a workpiece according to the third embodiment includes four steps: a modified layer forming step (S31), a thinning step (S32), a removal step (S33), and a film removal step (S34).

In the modified layer forming step (S31), the first modified layer 11 is formed in the same manner as that in the first embodiment. The first modified layer 11 is formed inside the first workpiece 100 in the same manner as that in the first embodiment (see FIG. 5). In this step, preferably, the first modified layer 11 is formed such chat the crack 12 developed from the first modified layer 11 reaches to appear on the front surface 101 side of the first workpiece 100.

The subsequent thinning step is performed in the same manner as that in the first embodiment, for example, by grinding the exposed surface (back surface 102) of the first workpiece 100 using the grinding apparatus 60 to a finished thickness (S32). While the thinning step (S32) is being performed, the removal step (S33) is performed simultaneously. The removal step is a process in which the chamfered portion 110 partitioned by the first modified layer 11 and the bonding interface between the first workpiece 100 and the second workpiece 200 is separated and removed from the workpiece W.

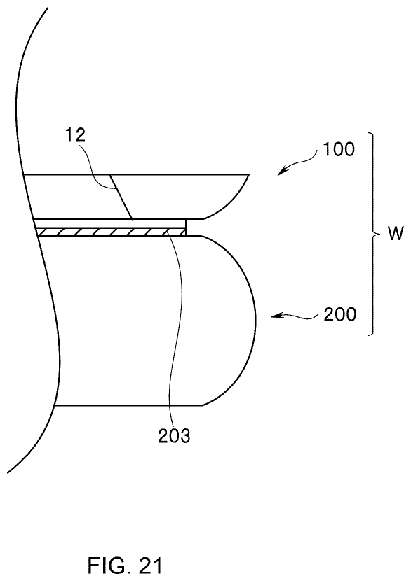

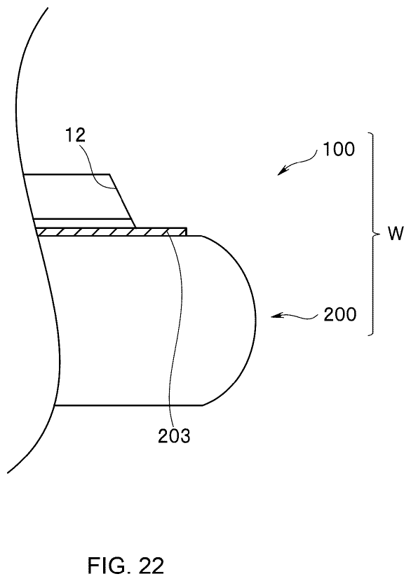

FIG. 21 is a partial cross-sectional view illustrating a state in the thinning step according to the third embodiment. As the first workpiece 100 is thinned further by grinding, the crack 12 appears exposed from the upper surface, as shown in FIG. 21. In this state, when grinding with the grindstones 624 progresses further, as shown in FIG. 22, the grinding force acts from the back surface 102 side of the first workpiece 100 as an external force, and the chamfered portion 110 is removed from the workpiece W where the first modified layer 11 and the bonding interface between the first workpiece 100 and the second workpiece 200 act as the separation starting points. FIG. 22 is a partial cross-sectional view illustrating a state in the thinning step according to the third embodiment. FIG. 22 is a partial cross-sectional view of the workpiece W at the end of the thinning step. When the thinning step (also performed as the removal step) is completed, in the trimming region TR, which is a region located outward from the first modified layer 11 (crack 12), the chamfered portion 110 is removed and the film 203 formed on the front surface 201 of the second workpiece 200 is exposed.

Therefore, the film removal step is performed lastly to remove the region of the film 203 that is exposed in the trimming region TR (S34). The film removal step is performed in the same manner as the film removal step (S14) in the first embodiment. After the film removal step (S34) is completed, as shown in FIG. 13, the workpiece W is processed into the same shape as that of the workpiece W in the first embodiment when the film removal step is completed.

As described above, as in the present embodiment, even when solely the first modified layer 11 is formed, the chamfered portion 110 may be partitioned using the first modified layer 11 and the bonding interface between the first workpiece 100 and the second workpiece 200 as the separation starting points. Therefore, the modified layer forming step is simplified, leading to a reduction in processing costs.

Optionally, in the present embodiment as well, as in the first embodiment, the thinning step and the removal step may be performed independently serially. In this arrangement, either the thinning step or the removal step may be performed first. When the removal step is performed independently, removal of the chamfered portion 110 in the removal step is not limited to the method using the external force applied by the grinding apparatus 60 described above, but other external forces generated in other methods may be used. For example, a bite cutting apparatus may be used to apply stress load generated by a cutting blade as the external force, or a separating member such as a wedge or fluid may be inserted into the bonding interface between the first workpiece 100 and the second workpiece 200 to separate the chamfered portion 110.

Meanwhile, the bonding interface between the first workpiece 100 and the second workpiece 200 is bonded by Si—O—Si siloxane bonding. By supplying a fluid such as water, steam, mist, or ammonia to the bonding interface of the workpiece W from outside, the Si—O—Si bond may be converted into an Si—OH—OH—Si bond, thereby weakening the bonding strength at the outer periphery of the workpiece W. Accordingly, by supplying such a fluid to the bonding interface in the workpiece W when performing the removal step, the bonding strength may be weakened, and removal of the chamfered portion 110 in the removal step is reliably performed.

While several embodiments of the present disclosure have been described, these embodiments are presented merely as examples and are not intended to limit the scope of the invention. These novel embodiments may be implemented in various other forms, and may be omitted, substituted, or altered in various ways without departing from the spirit of the technical idea of the present invention. Such embodiments and modifications are included within the scope and gist of the invention, as well as within the scope of the invention recited in the claims and equivalents thereof.

As described above, the method for processing a workpiece according to the present disclosure is advantageous when thinning a workpiece in which a first workpiece is fixed to a surface of a second workpiece, and, when using the second workpiece having a film formed on the surface thereof, particularly has the effect of suppressing contamination of the workpiece by the film that may otherwise peel off.

What is claimed is:

1. A method for processing a workpiece in which a first workpiece is fixed to a surface of a second workpiece, comprising:
forming a first modified layer along an annular region inside the first workpiece by emitting laser light at a position inward by a predetermined distance from an outer edge of the first workpiece;
removing at least a part of an outer peripheral portion of the first workpiece located outward from the first modified layer;
thinning the first workpiece to a predetermined thickness; and
removing a region of a film formed on the surface of the second workpiece, the region being laminated with the outer peripheral portion of the first workpiece.

2. The method according to claim 1, wherein forming the first modified layer includes further forming a second modified layer inside the first workpiece, the second modified layer developing on an outer side of the first modified layer and extending along a planar direction of the first workpiece toward the outer edge of the first workpiece.

3. The method according to claim 1, wherein forming the first modified layer includes further forming a third modified layer inside the second workpiece, the third modified layer developing on an outer side of the first modified layer and extending along a planar direction of the second workpiece toward an outer edge of the second workpiece.
